(19) United States
(12) Patent Application Publication
(10) Pub. No.: US 2017/0323762 A1
(43) Pub. Date: Nov. 9, 2017

(54) CHARGED PARTICLE BEAM APPARATUS, ELECTRON MICROSCOPE AND SAMPLE OBSERVATION METHOD

(71) Applicant: HITACHI HIGH-TECHNOLOGIES CORPORATION, Tokyo (JP)

(72) Inventors: Toshiyuki OOYAGI, Tokyo (JP); Takafumi YOTSUJI, Tokyo (JP); Isao NAGAOKI, Tokyo (JP)

(73) Assignee: HITACHI HIGH-TECHNOLOGIES CORPORATION, Tokyo (JP)

(21) Appl. No.: 15/525,147

(22) PCT Filed: Nov. 11, 2014
(86) PCT No.: PCT/JP2014/079861

§ 371 Date: May 8, 2017

(51) Int. Cl. H01J 37/26; H01J 37/28; H01J 37/20; H01J 37/18; H01J 37/02; H01J 37/302; G01N 1/28

(52) U.S. Cl. CPC H01J 37/261; H01J 37/3023; H01J 37/28; G01N 1/28; H01J 37/18; H01J 37/026; H01J 37/20

(57) ABSTRACT

An electron microscope includes: a sample holder; a first optical system irradiating and scanning the sample; an electron detection unit detecting secondary electrons discharged from the sample; a first vacuum chamber which holds the sample holder, the first optical system, and the electron detection unit in a vacuum atmosphere; a display unit displaying a microscopic image of the sample; and a control unit which controls the sample holder and the operation of the first optical system. The electron microscope includes a second vacuum chamber different from the first vacuum chamber, and a second optical system in the second vacuum chamber and is different from the first optical system. The second optical system and the control unit are capable of mutual communication, and the second vacuum chamber has a state changing means which changes the state of the sample.

### TECHNICAL FIELD

The present invention relates to a charged particle beam apparatus, an electron microscope, and a sample observation method.

### BACKGROUND ART

In sample observation using an electron microscope, “in-situ observation” is performed in order to dynamically observe an oxidation-reduction reaction or a change in a crystal structure, which is caused by gas introduction or heating. For example, these changes in a sample are imaged by a CCD camera, and a real-time image is displayed on a monitor so as to analyze the changes.

In order to perform “in-situ observation”, it is necessary to partition a high vacuum unit located inside the electron microscope and a low vacuum unit located in the vicinity of the sample to which gas is introduced or which is to be heated. A partitioning method includes a sealing method and a differential exhaust method. According to the sealing method, a sample space of low vacuum is created by a diaphragm. However, since the diaphragm exists in an electron beam path, it is difficult to obtain image resolution. In addition, according to the differential exhaust method, a gas atmosphere is created by exhaust resistance of a throttle. However, pressure is lower than that according to the sealing method.

For example, as a background technique in this technical field, PTL 1 discloses a technique. PTL 1 discloses “a sample holder that includes a sample loading unit having an opening for allowing an electron beam to pass therethrough, a heater wire stretched so as to cross a substantially central portion of the opening, a lead wire connected to both ends of the heater wire, and a capillary tube attached to face the heater wire so that gas blowing from a distal end thereof is blown to the heater wire”.

### CITATION LIST

### Patent Literature

PTL 1: JP-A-2003-187735

### SUMMARY OF INVENTION

### Technical Problem

According to the sample holder disclosed in PTL 1 described above, it is disclosed that the sample holder has a function capable of heating the sample in the gas atmosphere, and moreover, the sample holder can be used as it is for the electron microscope having a normal configuration.

However, whereas the sample holder has a relatively simple structure so as to be capable of introducing the gas to the vicinity of the sample and heating the sample, the sample holder needs to be sealed with the diaphragm. Consequently, it is difficult to obtain sufficient image resolution as described above.

According to an in-situ method for “in-situ observation”, the gas is introduced to the high vacuum unit inside the electron microscope. Thus, a gas type which can be introduced is limited. In addition, when reaction or a change in the sample is observed, it is not possible to measure temperature distribution of the sample inside a sample chamber of the electron microscope.

Therefore, an object of the present invention is to provide a charged particle beam apparatus which has low restriction on the conditions for changing the sample and which enables accurate in-situ observation of the sample with a relatively simple configuration.

In addition, another object of the present invention is to provide an electron microscope which has low restriction on the conditions for changing the sample and which enables accurate in-situ observation of the sample with a relatively simple configuration.

In addition, further another object of the present invention is to provide a sample observation method which has low restriction on the conditions for changing the sample and which enables accurate in-situ observation of the sample with a relatively simple configuration.

### Solution to Problem

In order to achieve the above-described objects, according to the present invention, there is provided a charged particle beam apparatus having a sample holder that supports a sample, a first optical system that irradiates the sample on the sample holder with a charged particle beam, an electron detection unit that detects a secondary electron discharged from the sample due to irradiation using the charged particle beam or a transmission electron transmitting through the sample, a first vacuum chamber that holds the sample holder, the first optical system, and the electron detection unit in a vacuum atmosphere, a display unit that displays a microscopic image of the sample, based on an output of the electron detection unit, and a control unit that controls each operation of the sample holder and the first optical system. The charged particle beam apparatus includes a second vacuum chamber that is different from the first vacuum chamber, and a second optical system that is disposed in the second vacuum chamber, and that is different from the first optical system. The second optical system and the control unit are connected to each other so as to be capable of mutual communication. The control unit can set the visual field position of the first optical system based on the image data after the state change of the sample transmitted from the second optical system. The second vacuum chamber includes state changing means for changing a state of the sample on the sample holder.

In addition, according to the present invention, there is provided an electron microscope having a sample holder that supports a sample, a first optical system that irradiates the sample on the sample holder with an electron beam, an electron detection unit that detects a secondary electron discharged from the sample due to irradiation using the electron beam or a transmission electron transmitting through the sample, a first vacuum chamber that holds the sample holder, the first optical system, and the electron detection unit in a vacuum atmosphere, a display unit that displays a microscopic image of the sample, based on an output of the electron detection unit, and a control unit that controls each operation of the sample holder and the first optical system. The electron microscope includes a second vacuum chamber that is different from the first vacuum chamber, and a second optical system that is disposed in the second vacuum chamber, and that is different from the first optical system. The second optical system and the control unit are connected to each other so as to be capable of mutual communication. The control unit can move the visual field position of the first optical system based on the image data after the state change of the sample transmitted from the second optical system. The second vacuum chamber includes state changing means for changing a state of the sample on the sample holder.

In addition, according to the present invention, there is provided a sample observation method using an electron microscope. The sample observation method includes acquiring an overall image of a sample serving as an observation target in a first sample chamber so as to subsequently acquire a first electron microscopic image of the sample in a second sample chamber, based on the acquired overall image of the sample, and acquiring the overall image of the sample while changing the sample in the first sample chamber so as to subsequently acquire a second electron microscopic image of the sample in the second sample chamber, based on the overall image of the sample which is acquired in the first sample chamber.

### Advantageous Effects of Invention

According to the present invention, it is possible to realize the charged particle beam apparatus which has low restriction on the conditions for changing the sample and which enables accurate in-situ observation of the sample with a relatively simple configuration.

In addition, according to the present invention, it is possible to realize the electron microscope which has low restriction on the conditions for changing the sample and which enables accurate in-situ observation of the sample with a relatively simple configuration.

In addition, according to the present invention, it is possible to provide the sample observation method which has low restriction on the conditions for changing the sample and which enables accurate in-situ observation of the sample with a relatively simple configuration.

An object, a configuration, and an advantageous effect in addition to those which are described above will be clarified by description of the following embodiments.

### BRIEF DESCRIPTION OF DRAWINGS

FIG. 1 is a view illustrating an overall scheme of an electron microscope according to an embodiment of the present invention.

FIG. 2A is a view partially illustrating an electron microscope according to an embodiment of the present invention.

FIG. 2B is a view illustrating a schematic configuration of an Ex-situ device according to an embodiment of the present invention.

FIG. 3 is a view illustrating temperature distribution display according to an embodiment of the present invention.

FIG. 4 is a view illustrating sample overall image display according to an embodiment of the present invention.

FIG. 5A is a view illustrating a sample observation system according to an embodiment of the present invention.

FIG. 5B is a view illustrating a sample observation system according to an embodiment of the present invention.

FIG. 6 is a flowchart illustrating a sample observation procedure according to an embodiment of the present invention.

FIG. 7 is a flowchart illustrating a sample observation procedure according to an embodiment of the present invention.

### DESCRIPTION OF EMBODIMENTS

Hereinafter, embodiment according to the present invention will be described with reference to the drawings. Throughout the description, the same reference numerals will be given to respectively the same configuration elements in respective drawings, and thus, description thereof may be omitted in some cases.

### Embodiment 1

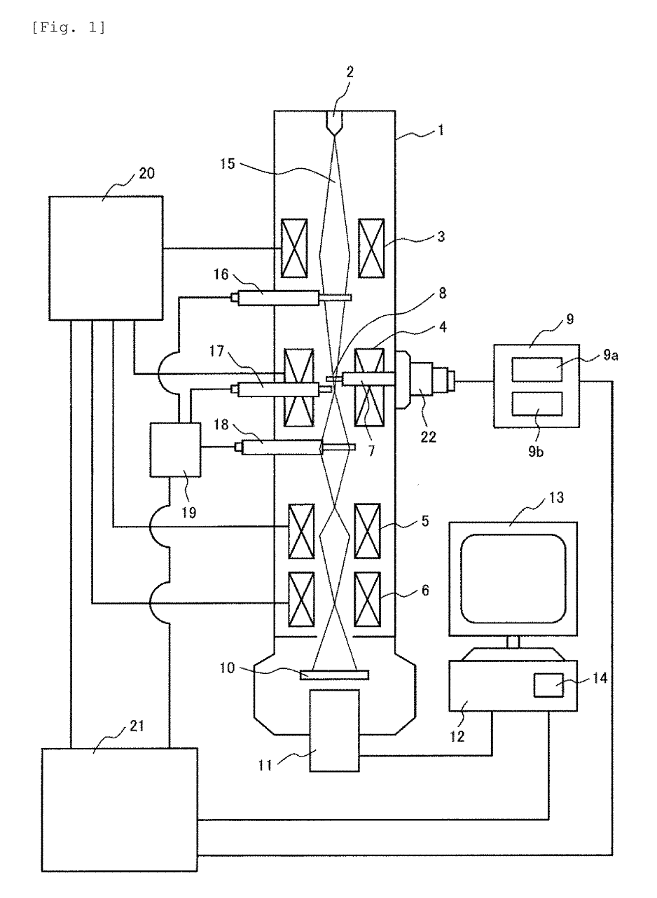

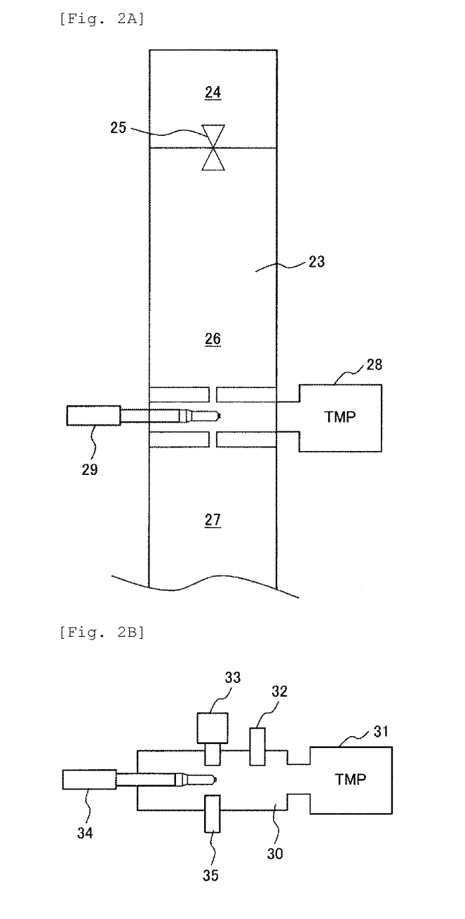

An electron microscope according to the present embodiment will be described with reference to FIGS. 1 to 2B. FIG. 1 illustrates an overall scheme of an electron microscope body. FIG. 2A illustrates the electron microscope body in FIG. 1 in a simplified manner in order to facilitate understanding. In addition, FIG. 2B illustrates a sample chamber 30 disposed separately from a sample chamber 27 in FIG. 2A.

First, the electron microscope body illustrated in FIG. 1 will be described. In the present embodiment, as an example of the electron microscope, description will be made with reference to an example of a transmission electron microscope which acquires a transmission electron image by causing a transmission electron detection unit to detect a transmission electron passing through the sample, and which scans the sample with the charged particle beam.

In addition, FIG. 1 illustrates an example of a transmission electron microscope which acquires a transmission electron image by causing a transmission electron detection unit to detect a transmission electron passing through the sample. However, without being limited thereto, the electron microscope serving as a target of the present invention may be a scanning electron microscope which acquires a secondary electron image by causing a secondary electron detection unit to detect a secondary electron discharged from the sample. Furthermore, a scanning/transmission electron microscope may be employed which includes both the transmission electron detection unit and the secondary electron detection unit.

An optical column of an electron microscope 1 is configured to mainly include an electron gun 2, a condenser lens 3, an objective lens 4, an intermediate lens 5, and a projection lens 6.

A sample 8 is loaded on a sample holder 7. The sample holder 7 is introduced into the inside from a sample stage 22 disposed on a side surface of the optical column of the electron microscope 1. Moving and tilting of the sample 8 are controlled by a sample fine movement drive mechanism 9 connected to the sample stage 22.

A convergence movable throttle 16 for converging a charged particle beam used in irradiating the sample 8, that is, an electron beam 15, is disposed above the objective lens 4. An object movable throttle 17 is provided on a rear focal plane of the objective lens 4. In addition, a limited view movable throttle 18 is provided on an image plane. Each movable throttle is connected to a movable throttle drive control unit 19. Each movable throttle is movable in a horizontal direction. The operation of each movable throttle is controlled by the movable throttle drive control unit 19 so as to move in and out on an optical axis in accordance with an observation target.

A fluorescent plate 10 is disposed below the projection lens 6. A camera 11 is mounted on a lower portion of the fluorescent plate 10. The camera 11 is connected to a monitor 13 and an image analysis device 14 via a camera control unit 12.

Each lens of the condenser lens 3, the objective lens 4, the intermediate lens 5, and the projection lens 6 is connected to a lens power source 20.

The charged particle beam discharged from the electron gun 2, that is, the electron beam 15 is converged by the condenser lens 3 and the convergence movable throttle 16, and is used in irradiating the sample 8. The electron beam 15 transmitted through the sample 8 is caused to form an image by the objective lens 4. The image is enlarged by the intermediate lens 5 and the projection lens 6, and is projected on the fluorescent plate 10. If the fluorescent plate 10 is moved so as to be shifted from an optical axis, the image is projected on the camera 11. The projected image is displayed on the monitor 13, and is recorded on the image analysis unit 14.

The main body control unit 21 is connected to the sample fine movement drive mechanism 9, the camera control unit 12, the movable throttle drive control unit 19, and the lens power source 20 so as to transmit and receive a control signal for controlling the overall apparatus. The sample fine movement drive mechanism 9 is configured to include a sample moving mechanism 9a for moving the sample 8, and a sample tilting mechanism 9b for tilting the sample 8.

A configuration of a control system illustrated in FIG. 1 is merely an example. As long as a function intended in the present embodiment is satisfied, any modification example for the control unit or communication wiring is included in the scope of the electron microscope according to the present embodiment. For example, in FIG. 1, the main body control unit 21 is connected to each configuration unit so as to control the overall apparatus. However, a configuration can be adopted which includes control units which are respectively independent for each configuration unit.

Next, a configuration according to the present embodiment will be described with reference to FIGS. 2A and 2B.

As described above, FIG. 2A illustrates the electron microscope body of FIG. 1 in a simplified manner. An optical column 23 of the electron microscope is configured to include an electron gun chamber 24, a gun valve 25, an intermediate chamber 26, a sample chamber 27, and a turbo molecular pump 28. A sample loaded on a sample holder 29 is inserted into the sample chamber 27 maintained in a high vacuum state by the turbo molecular pump 28, thereby performing observation on the sample.

FIG. 2B illustrates an Ex-situ device disposed separately from the optical column 23 in FIG. 2A. The Ex-situ device is configured to include a sample chamber 30 which is disposed separately from the sample chamber 27 and which brings the sample into a vacuum state, a turbo molecular pump 31 which evacuates the sample chamber 30, a vacuum gauge 32, a CCD camera 33 which fetches an image, a sample holder 34, and a gas introduction device 35.

Here, the sample holder 29 in FIG. 2A and the sample holder 34 in FIG. 2B can employ respectively different sample holders. However, for precise “in-situ observation”, it is preferable to use the same sample holder as in Embodiment 2 or Embodiment 3 (to be described later).

For example, the gas introduction device 35 is sample state changing means for supplying gas so as to cause an oxidation-reduction reaction in the sample.

As a method of changing a state of the sample, it is conceivable to use heating the sample, cooling the sample, irradiating the sample with ultraviolet light, or pressurizing the sample, in addition to changing a state of the sample by means of gas introduction. Therefore, in addition to the gas introduction device, the sample state changing means can be switched to a heating device for heating the sample, a cooling device for cooling the sample, an ultraviolet irradiation device for irradiating the sample with the ultraviolet light, or a pressurizing device for pressurizing the sample.

The CCD camera 33 is an optical system disposed inside the sample chamber 30 so as to observe a state of the sample on the sample holder 34. The optical system may have any configuration as long as the optical system can fetch an image. For example, in addition to an optical camera such as the CCD camera, the optical system can be switched to an optical microscope, or a thereto camera (infrared camera) for measuring a temperature.

Here, the sample chamber 27 in FIG. 2A and the sample chamber 30 in FIG. 2B are evacuated by respectively independent turbo molecular pumps (TMP) 28 and 31. For example, even if gas is introduced into the sample chamber 30 by the gas introduction device 35 in order to change a state of the sample, it is possible to prevent the gas from contaminating the sample chamber 27, that is, the electron microscope.

The sample chamber 27 and the sample chamber 30 include respectively independent vacuum system, and thus, can be maintained to have respectively different vacuum degrees. However, if the vacuum degree of the sample chamber 30 and the vacuum degree of the sample chamber 27 are caused to match each other, when a state of the sample is changed inside the sample chamber 30, it possible to observe a change in the sample under substantially the same condition as that of “in-situ observation” performed by the electron microscope.

In addition, the vacuum gauge 32 is disposed in the sample chamber 30. While the vacuum degree inside the sample chamber 30 is monitored, it is possible to change the state of the sample.

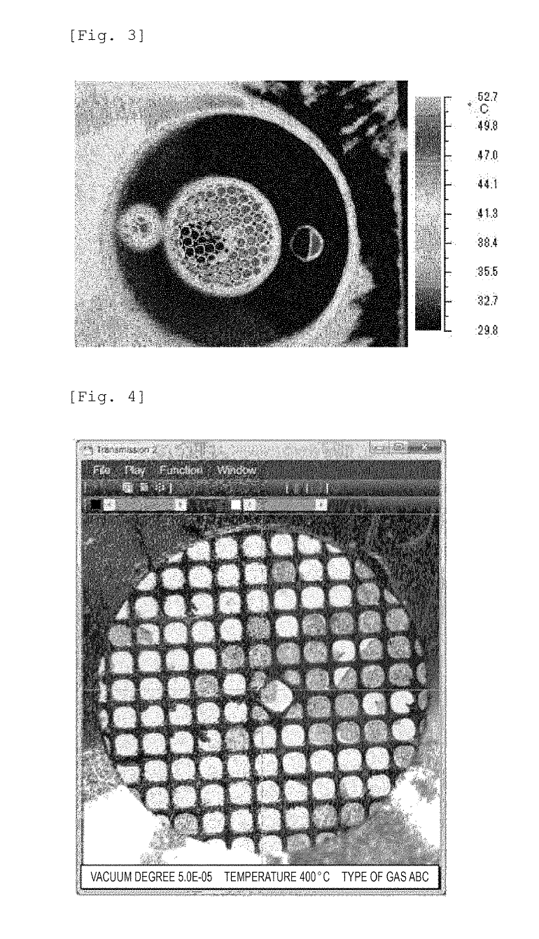

As the optical system of the Ex-situ device illustrated in FIG. 2B, the thermo camera (infrared camera) is mounted thereon instead of the CCD camera 33. FIG. 3 illustrates an example of temperature distribution of the sample when the sample is observed using the thermo camera.

As illustrated in FIG. 3, the optical system is exchanged from the CCD camera to the thermo camera. In this manner, it is possible to dynamically observe a temperature change in the sample while the sample is heated, for example.

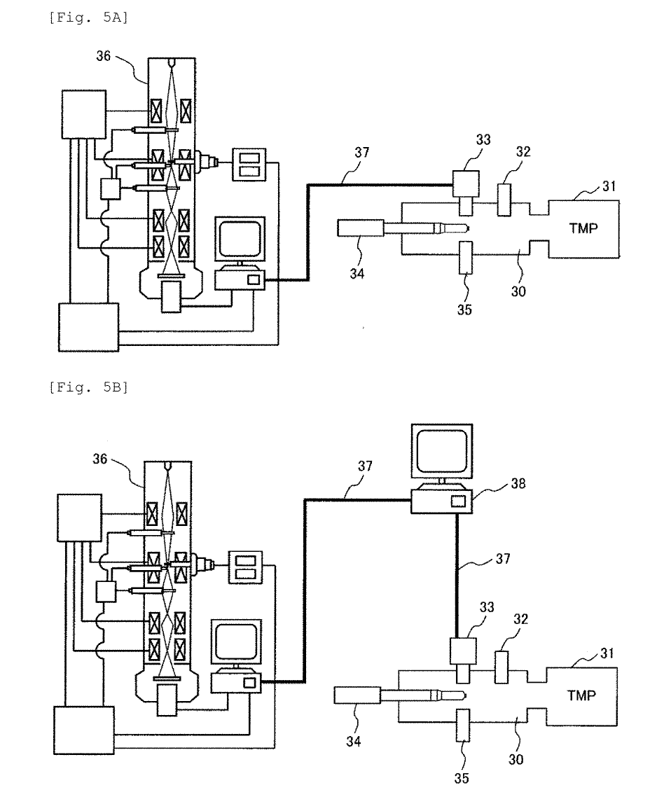

FIG. 4 illustrates an example in which the CCD camera is mounted thereon as the optical system of the Ex-situ device, and in which an overall image of the sample is observed using the CCD camera so as to be displayed on the monitor. A desired visual field position is determined on the overall image of the sample, and image data of the entire sample is transmitted to the electron microscope. In this manner, when the sample is observed using the electron microscope, a visual field can be easily moved to the desired visual field position.

In addition, as illustrated in FIG. 4, the sample for the electron microscope is observed in advance using the optical system such as the CCD camera of the Ex-situ device. Accordingly, the orientation of the sample can be aligned, and the sample can be positioned in a linkage with the electron microscope. Through the observation performed by the Ex-situ device, it is possible to acquire the sample overall image having no damage caused by the charged particle beam (electron beam).

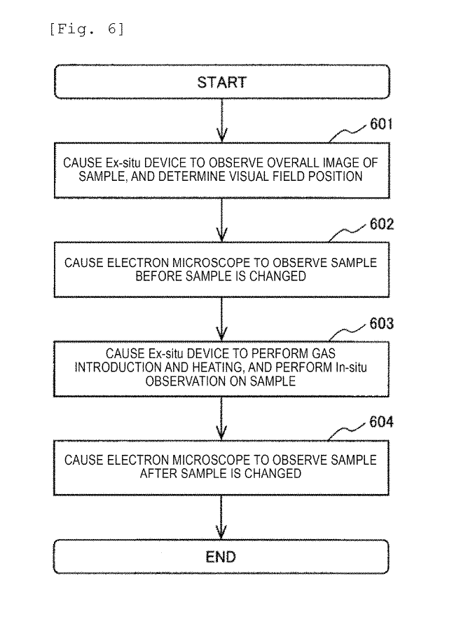

FIGS. 5A and 5B illustrate an example in which the electron microscope body described in FIGS. 1 and 2A and the Ex-situ device described in FIG. 2B are connected to each other.

In FIG. 5A, the CCD camera 33 of the Ex-situ device is linked to an electron microscope 36 via LAN connection 37. For example, in this case, Ex-situ device control software is installed in the main body control unit 21 or the image analysis unit 14 of the electron microscope 36. In this manner, the sample overall image captured by the CCD camera 33 of the Ex-situ device can be fetched to the electron microscope 36.

In FIG. 5B, a personal computer (PC) 38 is disposed between the CCD camera 33 of the Ex-situ device and the electron microscope 36. The CCD camera 33 and the personal computer (PC) 38, and the electron microscope 36 and the personal computer (PC) 38 are respectively connected to each other by each LAN connection 37. In this case, the Ex-situ device control software is installed in the personal computer (PC) 38. In this manner, the sample overall image captured by the CCD camera 33 of the Ex-situ device can be fetched to the electron microscope 36.

According to the system configuration as illustrated in FIG. 5B, the Ex-situ device illustrated in FIG. 2B can be relatively easily and additionally disposed in the existing electron microscope 36.

The LAN connection 37 is not limited to a wired LAN, and may be wireless communication using a wireless LAN. In addition, as long as the CCD camera 33 of the Ex-situ device and the electron microscope 36 are connected to each other so as to capable of mutual communication, other communication means may be used instead of the LAN connection 37.

### Embodiment 2

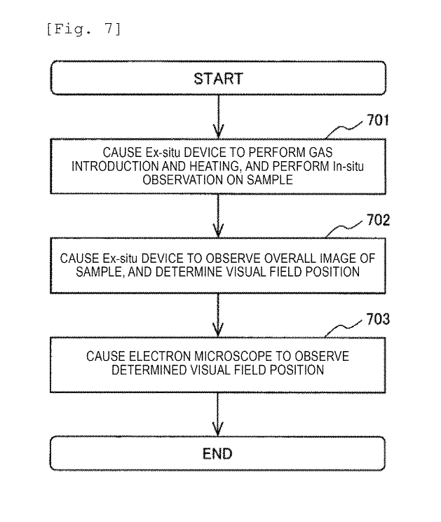

FIG. 6 illustrates an example of a sample observation procedure using the electron microscope described in Embodiment 1. The example of the sample observation procedure will be described with reference to a flowchart in FIG. 6.

First, the sample holder 34 having the sample loaded thereon is inserted into the Ex-situ device, and the overall image of the sample is observed (captured) by the optical camera such as the CCD camera 33, thereby confirming and determining a visual field position (Step 601). Here, a state of the sample loaded on the sample holder 34 or the rotation (position) is adjusted.

Next, the sample holder 34 is removed from the Ex-situ device, and is inserted into the sample chamber 27 of the electron microscope 1.

Here, in order to set the visual field position of the sample in the electron microscope 1, image data is transmitted from the Ex-situ device to the electron microscope 1. As described in Embodiment 1, means for transmitting the image data shares the data according to the system configuration in FIG. 5A or FIG. 5B.

When the sample is observed using the electron microscope 1, the visual field position can be moved, based on the image data transmitted from the Ex-situ device. Thus, it is not necessary to irradiate the sample with the electron beam by searching for the visual field. At the visual field position determined in advance when the sample is observed using the Ex-situ device, the sample having a high resolution image before being changed is observed (Step 602).

After the sample before being changed is observed, the sample holder 34 is inserted again into the Ex-situ device, and is subjected to processes such as gas introduction, heating, cooling, irradiation with the ultraviolet light, or pressurizing. The respective processes may be performed independently. For example, the gas introduction and the heating can be simultaneously performed. A plurality of the processes can be performed in combination with each other.

In order to observe a state where the sample is changed in the Ex-situ device, the CCD camera or the thermo camera performs in-situ observation (Step 603).

An image fetched by the CCD camera or the thermo camera displays an observation state on real-time basis. Accordingly, it is possible to store the image as a moving image. The vacuum degrees or the heating temperatures during the gas introduction are sequentially displayed on a graphical user interface (GUI).

After the change of the sample is observed using the CCD camera of the Ex-situ device, the sample is observed again using the electron microscope (Step 604).

As described above, in accordance with the sample observation procedure illustrated in FIG. 6, the high resolution image before and after the sample is changed is acquired. Accordingly, it is possible to compare the samples before and after the sample is changed.

In addition, the gas introduction is performed outside the electron microscope. Accordingly, in-situ observation can be performed using a type of gas which cannot be introduced into a high vacuum state.

### Embodiment 3

FIG. 7 illustrates another example of the sample observation procedure.

First, the sample holder 34 having the sample loaded thereon is inserted into the Ex-situ device, and is subjected to processes such as gas introduction, heating, cooling, irradiation with the ultraviolet light, or pressurizing. Similarly to Embodiment 2, the respective processes may be performed independently. For example, the gas introduction and the heating can be simultaneously performed. A plurality of the processes can be performed in combination with each other.

In order to observe a state where the sample is changed in the Ex-situ device, the CCD camera or the thermo camera performs in-situ observation (Step 701).

Subsequently, the overall image of the sample is observed using the CCD camera or the thermo camera, and the visual field position of the sample is determined in order to observe the sample in the electron microscope 1 (Step 702).

Next, the sample holder 34 is removed from the Ex-situ device, and is inserted into the sample chamber 27 of the electron microscope 1.

Here, in order to set the visual field position of the sample in the electron microscope 1, image data is transmitted from the Ex-situ device to the electron microscope 1. As described in Embodiment 1, means for transmitting the image data shares the data according to the system configuration in FIG. 5A or FIG. 5B.

When the sample is observed using the electron microscope 1, the visual field position can be moved, based on the image data transmitted from the Ex-situ device. Thus, it is not necessary to irradiate the sample with the electron beam by searching for the visual field. At the visual field position determined in advance when the sample is observed using the Ex-situ device, the sample having a high resolution image before being changed is observed (Step 703).

As described above, in accordance with the sample observation procedure illustrated in FIG. 7, a state of the sample is changed in the sample chamber 30 of the Ex-situ device different from that of the sample chamber 27 of the electron microscope 1. Thereafter, the high resolution image of the sample after being changed is acquired by the electron microscope.

The gas introduction is performed outside the electron microscope. Accordingly, similarly to Embodiment 2, in-situ observation can be performed using a type of gas which cannot be introduced into the sample chamber (high vacuum state) of the electron microscope.

In the Ex-situ device, the sample is observed using the optical camera such as the CCD camera. Accordingly, the electron microscope is suitably used in observing the sample which is weak in the electron beam.

In addition, before the sample is observed using the electron microscope, the visual field of the sample is searched for. Accordingly, it is possible to reduce damage to the sample which is caused by the electron beam.

In addition, data relating to the visual field position of the sample is transmitted from the Ex-situ device to the electron microscope. In this manner, without confirming the sample irradiated with the electron beam, it is possible to move the visual field position.

In addition, the Ex-situ method enables in-situ observation to be performed on a type of gas which cannot be introduced into the high vacuum state of the electron microscope. Therefore, it is possible to observe the sample and to dynamically observe a temperature change in the sample while the sample is heated.

It is more preferable that the temperature distribution acquired by the thermo camera described in FIG. 3 is displayed using color images. The reason is that a state of the temperature change inside the sample can be easily confirmed by changing the type of gas or the heating temperature.

In addition, the optical camera (CCD camera) and the thermo camera are switched therebetween so as to acquire images. In this manner, it is also possible to confirm the temperature distribution of a small shape inside the sample by superimposing the respective images on each other.

Furthermore, it is also possible to very accurately observe the temperature by superimposing the electron microscope image thereon.

In addition, the electron microscope described in the above-described respective embodiments employs the transmission electron microscope which acquires the transmission electron image by using the transmission electron transmitted through the sample. In this manner, it is possible to observe not only a surface change in the sample but also an internal change in the sample.

The present invention is not limited to the above-described embodiments, and includes various modification examples. For example, the above-described embodiments have been described in detail in order to facilitate the understanding of the present invention. The present invention is not necessarily limited to those which have all of the described configurations. In addition, a configuration of one embodiment can be partially replaced with a configuration of the other embodiment. In addition, the configuration of the other embodiment can be added to the configuration of one embodiment. In addition, with regard to a partial configuration of the respective embodiments, the other configuration can be added thereto, deleted therefrom, or replaced therewith.

### REFERENCE SIGNS LIST

1 ELECTRON MICROSCOPE,
2 ELECTRON GUN,
3 CONDENSER LENS,
4 OBJECTIVE LENS,
5 INTERMEDIATE LENS,
6 PROJECTION LENS,
7, 29, 34 SAMPLE HOLDER,
8 SAMPLE,
9 SAMPLE FINE MOVEMENT DRIVE MECHANISM,
9a SAMPLE MOVING MECHANISM,
9b SAMPLE TILTING MECHANISM,
10 FLUORESCENT PLATE,
11 CAMERA,
12 CAMERA CONTROL UNIT,
13 MONITOR,
14 IMAGE ANALYSIS UNIT,
15 ELECTRON BEAM,
16 CONVERGENCE MOVABLE THROTTLE,
17 OBJECT MOVABLE THROTTLE,
18 LIMITED VIEW MOVABLE THROTTLE,
19 MOVABLE THROTTLE DRIVE CONTROL UNIT,
20 LENS POWER SOURCE,
21 MAIN BODY CONTROL UNIT,
22 SAMPLE STAGE,
23 OPTICAL COLUMN,
24 ELECTRON GUN CHAMBER,
25 GUN VALVE,
26 INTERMEDIATE CHAMBER,
27, 30 SAMPLE CHAMBER,
28, 31 TURBO MOLECULAR PUMP (TMP),
32 VACUUM GAUGE,
33 CCD CAMERA,
35 GAS INTRODUCTION DEVICE,
36 ELECTRON MICROSCOPE,
37 LAN CONNECTION,
38 PERSONAL COMPUTER (PC)

1. A charged particle beam apparatus having
a sample holder that supports a sample,
a first optical system that irradiates the sample on the sample holder with a charged particle beam,
an electron detection unit that detects a secondary electron discharged from the sample due to irradiation using the charged particle beam or a transmission electron transmitting through the sample,
a first vacuum chamber that holds the sample holder, the first optical system, and the electron detection unit in a vacuum atmosphere,
a display unit that displays a microscopic image of the sample, based on an output of the electron detection unit, and
a control unit that controls each operation of the sample holder and the first optical system, the charged particle beam apparatus comprising:
a second vacuum chamber that is different from the first vacuum chamber; and
a second optical system that is disposed in the second vacuum chamber, and that is different from the first optical system,
a state changing means that is disposed in the second vacuum chamber, and that changes a state of the sample on the sample holder,
wherein the second optical system and the control unit are connected to each other so as to be capable of mutual communication, and
wherein the control unit can set the visual field position of the first optical system based on the image data after the state change of the sample transmitted from the second optical system.

2. The charged particle beam apparatus according to claim 1,
wherein the state changing means includes at least one or more devices among a gas introduction device which introduces gas to the second vacuum chamber, a heating device which heats the sample, a cooling device which cools the sample, an ultraviolet irradiation device which irradiates the sample with ultraviolet light, and a pressurizing device which applies pressure to the sample.

3. The charged particle beam apparatus according to claim 1,
wherein the second optical system is any one of an optical microscope, a CCD camera, and a thermo camera.

4. The charged particle beam apparatus according to claim 1,
wherein the control unit determines a scanning area on the sample to be irradiated with the charged particle beam, based on an overall image of the sample on the sample holder, which is acquired by the second optical system.

5. An electron microscope having
a sample holder that supports a sample,
a first optical system that irradiates the sample on the sample holder with an electron beam,
an electron detection unit that detects a secondary electron discharged from the sample due to irradiation using the electron beam or a transmission electron transmitting through the sample,
a first vacuum chamber that holds the sample holder, the first optical system, and the electron detection unit in a vacuum atmosphere,
a display unit that displays a microscopic image of the sample, based on an output of the electron detection unit, and
a control unit that controls each operation of the sample holder and the first optical system, the electron microscope comprising:
a second vacuum chamber that is different from the first vacuum chamber; and
a second optical system that is disposed in the second vacuum chamber, and that is different from the first optical system,
a state changing means that is disposed in the second vacuum chamber, and that changes a state of the sample on the sample holder,
wherein the second optical system and the control unit are connected to each other so as to be capable of mutual communication, and
wherein the control unit can move the visual field position of the first optical system based on the image data after the state change of the sample transmitted from the second optical system.

6. The electron microscope according to claim 5,
wherein the state changing means includes at least one or more devices among a gas introduction device which introduces gas to the second vacuum chamber, a heating device which heats the sample, a cooling device which cools the sample, an ultraviolet irradiation device which irradiates the sample with ultraviolet light, and a pressurizing device which applies pressure to the sample.

7. The electron microscope according to claim 5,
wherein the second optical system is any one of an optical microscope, a CCD camera, and a thermo camera.

8. The electron microscope according to claim 5,
wherein the control unit determines a scanning area on the sample to be irradiated with the electron beam, based on an overall image of the sample on the sample holder, which is acquired by the second optical system.

9. A sample observation method using an electron microscope, comprising:
acquiring an overall image of a sample serving as an observation target in a first sample chamber so as to subsequently acquire a first electron microscopic image of the sample in a second sample chamber, based on the acquired overall image of the sample, and
acquiring the overall image of the sample while changing the sample in the first sample chamber so as to subsequently acquire a second electron microscopic image of the sample in the second sample chamber, based on the overall image of the sample which is acquired in the first sample chamber.

10. The sample observation method according to claim 9,
wherein the first electron microscopic image and the second electron microscopic image are any one of a secondary electron image or a transmission electron image.

11. The sample observation method according to claim 9,
wherein means for changing the sample in the first sample chamber includes at least one or more means among gas introduction means for introducing gas to the first sample chamber, heating means for heating the sample, cooling means for cooling the sample, ultraviolet irradiation means for irradiating the sample with ultraviolet light, and pressurizing means for applying pressure to the sample.

12. The sample observation method according to claim 9,
wherein means for acquiring the overall image of the sample in the first sample chamber is any one of an optical microscope, a CCD camera, and a thermo camera.

13. The charged particle beam apparatus according to claim 1,
wherein the microscopic image of the first optical system is superimposed on the image data.

14. The charged particle beam apparatus according to claim 1,
wherein the first vacuum chamber and the second vacuum chamber are provided with independent vacuum systems.

15. The charged particle beam apparatus according to claim 1,
wherein the state changing means is a gas introduction device for introducing a gas of a gas type that can not be introduced into a high vacuum into the second vacuum chamber.
